(19) United States
(12) Patent Application Publication
(10) Pub. No.: US 2025/0246687 A1
(43) Pub. Date: Jul. 31, 2025

(54) Conformal Solid-State Batteries and Methods for Producing and Using the Same

(71) Applicant: University of Maryland, College Park, College Park, MD (US)

(72) Inventors: Keith GREGORCZYK; Nam KIM, Hyattsville, MD (US); Sang Bok LEE, Clarksville, MD (US); Gary W. RUBLOFF, Clarksville, MD (US)

(73) Assignee: University of Maryland, College Park, College Park, MD (US)

(21) Appl. No.: 18/856,357

(22) PCT Filed: Apr. 14, 2023
(86) PCT No.: PCT/US2023/018690

§ 371 Date: Oct. 11, 2024

Related U.S. Application Data
(60) Provisional application No. 63/339,242, filed on May 6, 2022.
(60) Provisional application No. 63/363,104, filed on Apr. 15, 2022.

(51) Int. Cl. H01M 10/0585; C25D 11/02; G03F 7/00; H01M 4/02; H01M 4/04; H01M 4/139; H01M 50/11

(52) U.S. Cl. CPC H01M 10/0585; C25D 11/022; G03F 7/0035; H01M 4/0404; H01M 4/139; H01M 50/11; H01M 2004/028

(57) ABSTRACT

The present disclosure provides a conformal solid-state battery (SSB) and methods for producing and using the same. The SSBs produced using a method of the disclosure have a higher energy and power compared to similar solid-state batteries without conformal electric cells. Due to avoidance of using any liquid electrolytes, SSBs of the disclosure have increased safety, especially in cases of medical implants and/or during catastrophic failures, where reactions of liquid electrolytes with air and/or water can produce toxic and/or poisonous by products.

### CROSS-REFERENCE TO RELATED APPLICATIONS

This application claims the priority benefit of U.S. Provisional Application Nos. 63/363,104, filed Apr. 15, 2022, and 63/339,242, filed May 6, 2022, all of which are incorporated herein by reference in their entirety.

### STATEMENT REGARDING FEDERALLY FUNDED RESEARCH

This invention was made with government support under grant numbers DESC0001160 and DESC0021070 awarded by the U.S. Department of Energy. The government has certain rights in the invention.

### FIELD

The present disclosure relates to a method for producing a conformal solid-state battery from a solid substrate using a combination of electrochemical anodization and a semiconductor manufacturing process. In some embodiments, methods of the disclosure include using a semiconductor manufacturing process to produce a patterned solid substrate surface, and an electrochemical anodization process to produce nanopores within the patterned solid substrate surface. By conformally depositing various layers within the nanopores, a high energy, high power 3-dimensional solid-state battery is produced.

### INTRODUCTION

In volume and space limited applications, such as medical implants (defibrillators, etc.), transportation, satellite, portable electronics, mining and drilling equipment, etc., it is desirable to have a battery of minimal footprint area and/or total volume, while maintaining both high power and high energy. Furthermore, and especially in cases of biomedical applications, it is desirable to avoid using liquid electrolytes as they are toxic, poisonous, and/or pyrophoric. Replacing this liquid or gel electrolyte with a solid-state electrolyte (SSE) will increase safety, especially in cases of medical implants and/or during catastrophic failures, where reactions with air and water can produce additional toxic and/or poisonous by-products such as HF gas. The potential for such by-products being released during a failure event further highlights that safety concerns are dramatically increased when considering in-vivo devices.

Batteries using solid-state electrolytes (SSEs) are referred to as solid-state batteries (SSBs) and have been predicted to solve these concerns. Traditionally fabricated (e.g., ball milling, sintering, sputtering, etc.) SSEs, however, limit performance of the cells due to lower ionic conductivities as compared to their liquid analogues. These traditionally fabricated SSEs are not easily integrated into current battery manufacturing. In addition, SOA manufactured SSBs produce planar cells, where every component of the cell is co-planar to the substrate it is built on. These cells are forced to balance energy density and power density by carefully controlling the thicknesses of the cathode and electrolyte layers. If the cathode is too thick the SSB suffers in power performance as the ions in the cell physically have a longer distance to travel.

Comparison to conventional SSB fabrication technology can be considered in two ways: first (1) as compared to the state-of-the-art (SOA) liquid-based lithium ion batteries (LIBs), and, second (2), how the thin-film method disclosed herein compares to standard particle-based approaches. Firstly, in SOA LIBs, components are formed from aggregated solid particles. These particles are mixed with conductive and binding additives and spread onto a metal foil using doctor-blade cast fabrication. This fabrication approach, and the constraints of the liquid electrolyte, limits most batteries to simple shapes. Moreover, the liquid electrolytes in conventional LIBs pose severe health risks from their flammability and toxicity, especially in implantable, wearable, and transportation-based applications. Commonly used liquid electrolytes are pyrophoric and will, upon exposure to air or water, ignite immediately. The solid-electrolyte used in the present disclosure has additional benefits beyond safety, including, but not limited to, a wider temperature range of operation without loss to performance or damage to the device being powered. Furthermore, the thin-solid electrolyte of conformal batteries of the disclosure allows the battery to operate at orders of magnitude higher power than SOA LIBs.

Secondly, a particle-based method for producing SSBs uses a similar process as SOA LIBs, i.e., doctors' blade fabrication methods, sintering, roll-to-roll processing, etc. However, in particle-based method of producing SSBs, introduction of the solid electrolyte (also particles) further complicates the process, which often leads to poor contact at the electrode/electrolyte interface.

Therefore, there is a need for a method for producing SSBs that allows for intimate contact between the electrode/electrolyte interface at all points in the system, thereby preventing problems associated with conventional SSB production methods. There is also a need for a method for producing solid-state batteries having both high energy density and high power density.

### BRIEF SUMMARY

Some aspects of the disclosure provide a method for producing solid-state batteries with relatively high energy and high power without requiring the large foot-print of conventional solid-state batteries, such as those disclosed in commonly assigned U.S. Pat. No. 8,912,522, issued to Rubloff et al., which is incorporated herein by reference in its entirety. In some aspects, a method is provided for increasing the surface area of solid-state batteries using a nanoscale fabrication process.

Some of the key advantages of conformal batteries of the disclosure include, but are not limited to, higher energy density, higher power density, absence of binder and/or stabilizer, as well as having all components including the electrolyte layer being a solid.

In one particular aspect of the disclosure, a method of producing a conformal solid-state battery comprises producing a high-aspect ratio structured substrate from a solid substrate that comprises:
a mask layer;
a patternable layer; and
a base layer.
   As used herein, the term “high aspect ratio” refers to a ratio between pore diameter and pore depth of at least about 25:1, typically at least about 50:1, often at least about 75:1, and most often at least about 100:1. Thus, the method of disclosure includes:
patterning said mask layer using lithography to produce a patterned solid substrate comprising a patterned patternable layer surface;
nano-patterning said patterned patternable layer surface to produce a high-aspect ratio structured substrate comprising a plurality of nanopores within said patternable layer surface; and
conformally and sequentially depositing into said high-aspect ratio structured substrate a first current collector layer, an electrode layer, a solid electrolyte layer, a counter electrode layer, a counter current collector layer; and optionally a top contact layer to produce said conformal solid-state battery having a nanostructured solid substrate.

In some embodiments, the method can also include removing at least a portion of said counter electrode layer and said counter current collector layer from said nanostructured solid substrate.

It should be appreciated, other intermediate layer(s) can be deposited between any of the layers disclosed herein. For example, one can deposit an “adhesive layer” between any the base layer and the patternable layer to provide a better bonding between the two layers.

A patternable layer refers to any solid material that can be micro- or nano-patterned. As used herein, the term “nano-patterned” includes micro-patterned material and refers to a three-dimensional nano-structured solid material in which the surface has been patterned to include nano-pores, typically in an ordered manner. The term nano-pore refers to pores having a pore diameter as defined herein. Typically, the nano-patterned layer of the disclosure has an ordered structure, e.g., nanostructure having periodicity or repeating patterns. However, it should be appreciated that the scope of the disclosure includes conformal batteries having an ordered or a disordered nano-patterned layer.

In general, the base layer can be any solid material that conducts electricity. Exemplary materials suitable for a base layer includes, but are not limited to, any and all types of metals, alloys thereof, oxides thereof, nitrides thereof, as well as electric conducting polymers. In one particular embodiment, the base layer comprises Cu, Au, Pt, Ti, Ru, Ag, Pd, etc., an oxide or a nitride thereof, a polymer, or a combination thereof. Electric conducting polymers are well known to one of ordinary skill in the art. Exemplary electric conducting polymers include, but are not limited to, poly(3,4-ethylenedioxythiophene) (i.e., PEDOT), poly(fluorine), polypyrrole, polyaniline, poly(p-phenylene vinylene), polythiophene, poly(acetylene), and the like.

Still in other embodiments, said solid substrate further comprises a valve metal layer in between said patternable layer and said base layer. Typically, a valve metal layer is any material known to one skilled in the art such as, but not limited to, W, Ta, Ti, Nb, Nd, etc. or a mixture thereof. In some embodiments, said patternable layer comprises an anodizable metal. In these embodiments, said step of nano-patterning said patterned patternable layer surface comprises electrochemically anodizing said patternable layer until said valve metal layer begins to oxidize thereby forming a valve metal oxide plug. Yet in further instances, the method further comprises the step of removing said valve metal oxide plug. In other embodiments, the valve metal and the patternable layer can be the same material.

Yet in other embodiments, said solid substrate further comprises a carrier body below said base layer. In some instances, said carrier body comprises a silicon wafer, an aluminum oxide wafer, a porous aluminum oxide wafer, a polymer, a web-tensioned polymer roll, a polymer foil, a metal foil, a metal disc, a polymer disc, a metal sheet, polymer sheet, a metal wire, a polymer wire, a metal fiber, a polymer fiber, a natural fiber, a weave of fibers, a linen, or textile or a combination thereof.

Still yet in other embodiments, said masking layer comprises SiO₂ coated with a positive or a negative photoresist.

In further embodiments, said step of patterning said mask layer comprises photolithography, interference lithography, electron beam lithography, optical lithography, x-ray lithography, ion beam lithography, diffraction lithography, direct write lithography, direct write laser lithography, laser lithography, or other lithography techniques known to one skilled in the art.

Yet in other embodiments, each of said step of conformally depositing said first current collector layer, said electrode layer, said solid electrolyte layer, said counter electrode layer, said counter current collector layer; and optionally said top contact layer independently comprises an atomic layer deposition, chemical vapor deposition, electrochemical deposition, molecular layer deposition, plasma-enhanced chemical atomic layer deposition, plasma-enhanced chemical vapor deposition, or another type of vapor phase deposition method, or another type of physical deposition method, or any combination thereof.

In one particular embodiment, said first current collector layer is a cathode current collector. In this instance, said electrode layer is a cathode layer.

Still in further embodiments, said solid electrolyte layer has an ionic conductivity of at least 1×10⁻⁷ S/cm² at 25° C. In some instances, said solid electrolyte layer comprises lithium phosphorus oxynitride (LiPON) or a polymorph of LiPON, lithium aluminum titanium phosphate (LATP), NASICON, a lithium garnet (such as; Li₆La₂BaTa₂O₁₂), lithium lanthanum titanate (LLTO), LISICON (such as; Li₁₄ZnGe₄O₁₆), Thio-LISICON (such as Li_{3.4}Si_{0.4}P_{0.6}S₄), a composite such as LiI—Al₂O₃, LiNbO₃, a hybrid organic/inorganic material, a polymer (e.g., polyethylene oxide (PEO), polyacrylonitrile (PAN), polymethyl methacrylate (PMMA), or polyvinylidene fluoride), a sulfide (e.g., LiSON and LiBSO), a fluoride (e.g., LiF), an oxy-sulfide (e.g., LiSO), an oxy-fluoride (e.g., LiFO), or a combination or a composite thereof (e.g., PEO mixed with LiO₂).

Another aspect of the disclosure provides a conformal solid-state battery having an energy density of at least about 1 μWh/cm², typically at least about 1×10³ μWh/cm², more typically at least about 1×10⁴ μWh/cm², often at least about 2×10⁴ μWh/cm², and most often at least 3×10⁴ μWh/cm² and a power density of at least 1 W/cm², typically at least about 2 W/cm², more typically at least about 1×10⁴ W/cm², often at least about 2×10⁴ W/cm², and most often at least 1×10⁷ W/cm². As used herein, the term “conformal solid-state battery” refers to a three-dimensional solid-state battery in which each layer of the components (e.g., electrodes, electrical conductors or current collectors, electrolytes, etc.) of the battery has a relatively uniform thickness throughout the 3D system. The term “uniform thickness” refers to having a variation no more than 2 and often no more than 1 standard deviation of thickness. Alternatively, the term “uniform thickness” refers to having no more than 50%, typically no more than 40%, often no more than 30%, more often no more than 25%, still more often no more than 20%, and most often no more than 10% thickness variation of a particular component throughout the 3D solid-state battery.

In some embodiments, the conformal solid-state battery has a pore density of at least about 1.15×10⁶ pores/cm², typically, about 5.13×10⁷ pores/cm², often about 5.70×10⁸ pores/cm², and most often about 1.15×10¹⁰ pores/cm².

Yet in other embodiments, the conformal solid-state battery has energy density of at least about 100 times or more, typically at least about 125 times or more, often at least 150 times or more, more often at least about 175 times or more, and most often at least 200 times or more than a same solid-state battery in a planar state. As used herein the term “same solid-state battery in a planar state” refers to a battery having a same thickness of components that are stacked on top of each other in a two-dimensional (i.e., non-conformal) manner. Unlike conformal (e.g., high-aspect ratio structured) batteries in which there are nanopores within the anodization or patternable layer, batteries in a planar state do not have any nanopores. In fact, each components or layers in a planar state battery can be considered a block of component that is layered on top of each other. Throughout this disclosure, unless otherwise stated, the term “same solid-state battery in a planar state” refer to a battery having the same macro dimension (i.e., length×width×depth, without consideration of any pores in the 3D or conformal solid-state battery).

Still in another embodiment, an energy density of said conformal solid-state battery is at least 100 times greater, typically at least 125 times greater, often at least about 150 times greater, and most often at least about 200 times greater, than an energy density of a same SSB in a planar state at a current density of 10 μA/cm².

In further embodiment, an energy density of said conformal solid-state battery is at least 1,000 times greater, typically at least about 1250 time greater, and often at least about 1500 times greater than an energy density of a same SSB in a planar state at a current density of 0.5 mA/cm².

Another aspect of the invention provides a conformal solid-state battery (SSB) comprising:
a valve metal layer (4) having a top surface and a bottom surface;
anodization layer (5) having a top surface and a bottom surface, wherein said bottom surface of said anodization layer (5) is in contact with said top surface of said valve metal layer (4), and wherein said anodization layer (5) comprises a plurality of pores each of which has an interior surface and a bottom surface, wherein said bottom surface extends towards said bottom surface of said anodization layer (5) and optionally extends partially into said valve metal layer (4);
a first electrical conductor (12) that is conformally layered on top surface of said anodization layer (5) and extending to and from said bottom surface;
a first electrode layer (13) that is conformally layered on top of said first electrical conductor (12);
a solid electrolyte layer (14) that is conformally layered on top of said first electrode layer (13);
a second electrode layer (15) that is conformally layered on top of said solid electrolyte layer (14); and
a second electrical conductor (16) that is conformally layered on top of said second electrode layer (15).

In some embodiments, a material of said valve metal layer (4) is selected from the group consisting of W, Ta, Ti, Nb, Nd, and a combination thereof. Yet in other embodiments, a material of said anodization layer (5) is selected from the group consisting of Al, Ti, Mg, and a combination thereof. Still in other embodiments, said first electrical conductor (12) has an electrical resistivity of about 500×10³ (i.e., 5×10⁵) μΩ cm or less. In further embodiments, said first electrode layer (13) is a cathode comprising LiV₂O₅, Li₂V₂O₅, or a combination thereof. Still yet in other embodiments, said solid electrolyte layer (14) has an ionic conductivity of at least about 1×10⁻⁹ S/cm² at 25° C. Yet in another embodiment, said solid electrolyte layer (14) comprises lithium phosphorus oxynitride, lithium aluminum titanium phosphate (LATP), sodium super ionic conductor (NASICON), a lithium garnet, lithium lanthanum titanate (LLTO), lithium super ionic conductor (LISICON), Thio-LISICON, a lithium composite, LiNbO₃, a hybrid organic/inorganic material, a polymer, a lithium sulfide, lithium fluoride, a lithium oxy-sulfide, lithium oxy-fluoride, or a combination or a composite thereof. Still in other embodiment, said second electrode layer (15) has a capacity of at least about 500 mAh/g. In another embodiment, said second electrical conductor (16) has an electrical resistivity of about 5×10⁵ μΩ cm or less. In yet another embodiment, an average pore diameter is about 5 μm nm or less, typically about 2 μm or less, often about 5 μm or less and most often about 500 nm or less. Still in another embodiment, an average pore depth of said anodization layer (5) is about 100 μm or less, typically about 50 μm or less, often about 25 μm or less, and most often about 10 μm or less.

Another aspect of the disclosure provides a method for producing a conformal solid-state battery (SSB) or an array of conformal solid-state batteries, said method comprising:
coating an anodization layer with a photoresist mask;
patterning said photoresist mask using a lithography process to produce a patterned anodization layer having a top surface and a bottom surface, wherein said top surface is coated with said patterned photoresist mask;
anodizing said patterned anodization layer to produce an anodized layer having a plurality of pores on said top surface of said anodization layer, wherein each of said pores has an interior surface and a bottom surface, wherein said bottom surface extends towards said bottom surface of said anodized layer;
coating said anodized layer with a first electrical conductor to produce a conformally coated first electrical conductor layer;
coating said first electrical conductor layer with a first electrode layer to produce a conformally coated first electrode layer;
coating said first electrode layer with a solid electrolyte layer to produce a conformally coated electrolyte layer;
coating said electrolyte layer with a second electrode layer to produce a conformally coated second electrode layer; and
coating said second electrode layer with a second electrical conductor layer to produce a conformally coated second electrode layer.

In some embodiments, at least one of said coating step is conducted using an atomic layer deposition process.

Still in other embodiments, said step of anodizing said patterned anodization layer comprises contacting said patterned anodization layer with an electrolytic solution under an electrolytic process. Yet in other embodiments, said electrolytic solution comprises oxalic acid, sulfuric acid, hydrochloric acid, phosphoric acid, chromic acid, perchloric acid, ethanol, glycolic acid, tartaric acid, citric acid, malic acid, selenic acid, or any combination thereof.

### BRIEF DESCRIPTION OF THE DRAWINGS

FIG. 1 illustrates one particular embodiment of the disclosure for producing a conformal solid-state battery from a solid substrate using a combination of electrochemical anodization and a semiconductor manufacturing process.

### DETAILED DESCRIPTION

The present disclosure will now be described with regard to the accompanying drawings, which assist in illustrating various features of the disclosure. In this regard, the present disclosure generally relates to conformal solid-state batteries and methods for producing and using the same. That is, the disclosure relates to conformal batteries having a high power density and a high energy density. In some embodiments, the conformal batteries of the disclosure do not include any binder or stabilizer within any of the component layers. For the sake of clarity and brevity, the present disclosure will now be described in reference to using an anodization to produce a high-aspect ratio structured substrate. However, it should be appreciated that the high-aspect ratio structured substrate can be produced using any method known to one of ordinary skill. In particular, high-aspect ratio structured substrate can be produced by any corrugation process, e.g., electrochemical anodization, micropatterning lithography, as well as similar technology known to one of ordinary skill. Accordingly, it should be appreciated that the scope of the disclosure is not limited to merely electrochemically anodizing a patternable layer to produce a high-aspect ratio structured substrate. Therefore, use of an electrochemical anodization process is provided solely for the purpose of illustrating the practice of the disclosure to produce a high-aspect ratio structured substrate and do not constitute limitations on the scope thereof. It should be appreciated that the present disclosure generally relates to a method for producing nanostructured solid-state batteries, but the scope of the disclosure is not limited to the method disclosed herein but can be used generally to produce SSBs with various energy and power densities. It should also be appreciated that reference numerals designate elements in the individual figures. None of the references, however, are illustrated to scale. Rather, individual elements can be illustrated as excessively large or disproportionate to other elements for ease of understanding.

Enabling the fabrication of SSB at the nanoscale and over 3D substrates represents a structure-based approach to improve both power and energy performance of solid-state batteries. High power and energy densities can be achieved by increasing the surface area upon which an SSB is formed, while maintaining thin electrodes and well-defined locally 1D current distributions. Electrochemical processes have been used in semiconductor or CMOS manufacturing to produce nanopores within aluminum oxide on carrier bodies such as silicon wafers. Electrochemical anodization of aluminum to produce porous anodic aluminum oxide (AAO) on the surface of the carrier body in manufacturing semiconductors and CMOS is well known. These nanopores dramatically increase the surface area of AAO. The amount of surface area increase can be modulated by various parameters related to the anodization process including, but not limited to, temperature, electrolyte composition, anodization potential, post anodization processing such as annealing, pore widening, etc. By controlling each of these parameters the AAO nanopores formed can vary, e.g., from 40 nm to 450 nm in diameter and 500 nm to <50 um. The presence of nanopores dramatically increases the surface area of AAO. In some embodiments, the average diameter of nanopores ranges from about 10 nm to about 1 μm, typically from about 20 nm to about 750 nm, and often from about 40 nm to about 500 nm. However, it should be appreciated that the scope of disclosure is not limited to these particular pore sizes. In fact, the average pore size can range from about 1 nm to about 10 μm, typically from about 10 nm to about 5 μm, and often from about 20 nm to about 1 μm. When referring to a numerical value, the terms “about” and “approximately” are used interchangeably herein and refer to being within an acceptable error range for the particular value as determined by one skilled in the art. Such a value determination will depend at least in part on how the value is measured or determined, e.g., the limitations of the measurement system, i.e., the degree of precision required for a particular purpose. For example, the term “about” can mean within 1 or more than 1 standard deviation, per the practice in the art. Alternatively, the term “about” when referring to a numerical value can mean ±20%, typically ±10%, often ±5% and more often ±1% of the numerical value. In general, however, where particular values are described in the application and claims, unless otherwise stated, the term “about” means within an acceptable error range for the particular value, typically within one standard deviation.

Conformal deposition methods are able to grow or deposit a material evenly (e.g., within about 2, and typically within about 1 standard deviation thickness) over a highly textured or porous surface. For example, a nanopore that has a diameter of 500 nm and a depth of 5 μm, a conformal material would be equivalently thick at the bottom of the pore as it is at the top of the pore (e.g., within about 2, and typically within about 1 standard deviation thickness). A variety of industrial techniques are capable of such conformality and include; vapor phase vacuum deposition techniques like atomic layer deposition, molecular layer deposition, chemical vapor deposition, and/or their variations (e.g., plasma-enhanced, etc.) and equivalents. In fact, these methods are considered industry standard for the fabrication of memory and logic elements used universally in computing devices.

Solution based methods like electrochemical deposition and all of its variations, as well as dipped and casting methods using sol-gels are also used to produce conformal devices on an industrial scale. These techniques can also be used in methods disclosed herein to produce similar results. It is common in many semiconductor manufacturing facilities to use both vacuum deposition methods and electrochemical depositions in the same processing line (i.e., the damascene process, etc.).

Aerosol-based methods or particle-spray based methods in all of its variations. These methods can be done under vacuum conditions, they can also be done at standard atmospheric pressure, or at some pressure above atmospheric pressure. These techniques can also be used in methods disclosed herein to produce similar results.

By utilizing various processes in semiconductor manufacturing in combination with electrochemical processes, the present inventors have discovered that three-dimensional nanostructured solid-state batteries can be produced by conformally adding various layers for batteries. Moreover, the present inventors have discovered that forming solid-state batteries in and over highly porous substrates like porous anodic aluminum oxide on semiconductor processable carrier bodies allowed fabrication of batteries with energy and power densities equivalent to and higher than standard lithium-ion batteries. The method disclosed here is also versatile at many different points throughout the process.

Some aspects of the disclosure provide arrays of solid-state batteries and methods of forming arrays of solid-state batteries on a carrier body through a combination of electrochemical anodization and semiconductor manufacturing techniques. In at least one embodiment the batteries are lithium-ion batteries, in another they are sodium-ion batteries. However, it should be appreciated that the scope of disclosure is not limited to producing lithium-ion or sodium-ion batteries. In fact, the method disclosed herein can be used to produce any and all types of solid-state batteries known to one skilled in the art. For example, the method of disclosure can be used to produce arrays of any cation (K⁺, Mg²⁺, etc.) or anion (F⁻, etc.) based nano-scale solid-state batteries.

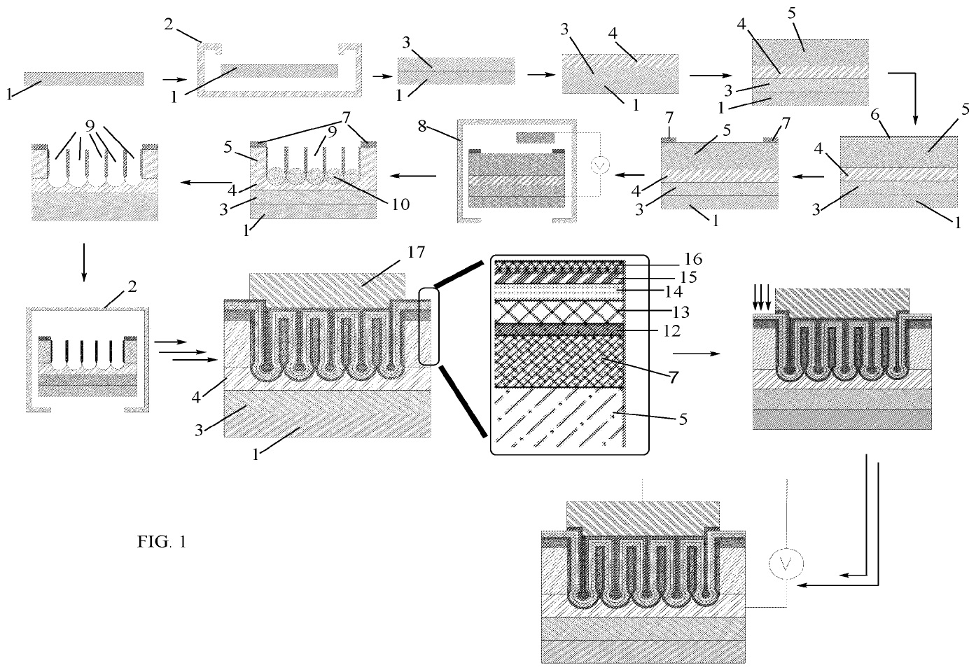

Referring to FIG. 1, a carrier body (1) is provided. The carrier body can be any solid substrate. For example, the carrier body (1) can be a wafer (e.g., a silicon wafer, an aluminum oxide wafer, a porous aluminum oxide wafer, etc.), a polymer, a web-tensioned polymer, a metal disc, linen, a series or array of metal discs, a wire, or a foil. In one particular embodiment, the carrier body (1) is silicon wafer that is 25.4 mm, 76.2 mm, 100 mm, 125 mm, or some other size of wafer, in diameter. The wafer can also range in from about 100 mm to about 450 mm in diameter. In still other embodiments the Si wafer is a square or rectangle shape. In another particular embodiment, the carrier body (1) is an N-doped silicon wafer, a p-doped silicon wafer, or an undoped silicon wafer.

The carrier body (1) is introduced into a deposition system (2). The deposition system (2) is designed to deposit layers evenly (i.e., within thickness variation of 2 standard deviation, typically within 1 standard deviation) and parallel to a three-dimensional surface, this property is referred herein as conformality. The deposition system (2) may be a physical deposition system such as a DC-sputtering system or RF-sputtering system or an evaporation system, it can also be a chemical vapor deposition system or atomic layer deposition system or a molecular layer deposition system. In another embodiment, the deposition system (2) is a plasma enhanced chemical deposition system, or plasma enhanced atomic or molecular layer deposition system. In some embodiments, the deposition system (2) contains multiple deposition methods such that the carrier body (1) may be coated with various material(s) by various methods.

Still in other embodiments, the deposition system (2) can be a cluster system such that many deposition systems (2) are coupled through vacuum or through robotic transfer or through manual transfer. In the case of a vacuum-based deposition system, the carrier body (1) is maintained at a pressure of from about 1×10⁻⁷ mbar to about 1000 mbar, typically from about 0.10 mbar to about 0.60 mbar, and often from about 0.20 mbar to about 0.250 mbar. It should be appreciated that the scope of the disclosure is not limited to these particular ranges of pressure. Depending on the materials, the pressure within the deposition system (2) can vary widely. The pressure of the deposition system (2) can be maintained at a constant pressure for some period of time during one particular process and then be changed to another pressure for another process. The pressure may also be atmospheric pressure or some pressure higher than atmospheric pressure.

In some embodiments, the deposition system (2) maintains the carrier body (1) at a temperature of from about 20° C. to about 500° C. The temperature of the carrier body (1) can vary during its time in the deposition system (2). The temperature can vary from room temperature to 200° C. or from 200° C. to 500° C. The temperature could be maintained for some time during the method and then changed to another temperature for another part of the method. The carrier body (1) can be maintained at a temperature from about −10° C. to about 10° C., it may also be maintained from about 250° C. to about 400° C. In another part of the method the carrier body (1) temperature could be maintained at 100° C. for a period of time. In one particular embodiment, the carrier body (1) is maintained at 2° C. for a period of at least one hour. The ramp rate for changes in temperature can also vary.

The deposition system (2) can also be an electrochemical deposition system which uses liquid electrolytes to deposit planar layers on flat surfaces or conformal layers in three-dimensional surfaces. In one particular embodiment, the deposition system (2) is a cluster tool that includes a vacuum to liquid transfer system, this transfer can also be done manually. In at least one embodiment, the cluster tool contains both an electrochemical deposition system and a vacuum-based deposition system. In particular, these systems can be coupled by robotics to allow facile manipulation. They may also require manual transfer of the carrier body (1) between each step. In still another embodiment, the electrochemical deposition system and the anodization system (8) can be the same system.

Referring again to FIG. 1, a metal layer (3) is deposited on top of the carrier body (1). The metal layer (3) can be deposited by vacuum-based methods or electrochemical based methods. In one particular embodiment, the metal layer (3) is formed by evaporation, in another embodiment, the metal layer (3) is deposited by sputtering. Still in another embodiment, the carrier body (1) is electrically conductive. Yet in a further embodiment, the metal layer (3) and the carrier body (1) are the same. In one particular embodiment, a 1 μm copper layer is deposited as the metal layer (3) onto a 100 mm diameter silicon wafer. In another specific embodiment, a 500 μm layer of copper is deposited as the metal layer (3) onto a 76.22 mm diameter silicon wafer. In yet another specific embodiment, an aluminum layer is used or an alloy of two metals is used as the metal layer (3). The thickness of the metal layer (3) can be between from about 1 nm to about 50 nm, it can also be between from about 50 nm to about 1 um, in yet another embodiment the thickness of the metal layer (3) is >1 μm.

Yet in other embodiments, an adhesive layer (not shown) can be deposited in between the carrier body (1) and the metal layer (3). For example, it is difficult to achieve tight binding between silicon wafer (carrier body (1)) and copper (metal layer (3)). Thus, to provide better attachment, an adhesive layer (e.g., titanium) can be placed on the surface of the carrier body (1) prior to depositing the metal layer (3). In this manner, one can achieve a good or tight bonding between the carrier body (1) and the metal layer (3). Exemplary materials suitable for adhesive layer include, but are not limited to, titanium, chromium, tungsten, niobium, and oxides thereof or a combination thereof.

Referring again to FIG. 1, a valve metal layer (4) is deposited on top of the metal layer (3) using a deposition system (2). The valve metal layer (4) can be any material that can self-grow nano-porous oxide films. Exemplary metals suitable for valve metal layer (4) include, but are not limited to, Al, W, Ti, Ta, Hf, Nb, Zr, and alloys thereof. In one particular embodiment, the valve metal layer (4) is W or Ta. In one particular embodiment, the valve metal layer (4), e.g., tungsten (W), is deposited by DC sputtering or electron beam evaporation. The valve metal layer (4) can also be deposited by RF-sputtering or chemical vapor deposition or plasma enhanced chemical vapor deposition. The thickness of the valve metal layer (4) can range from about 1 nm to about >1000 nm, typically from about 10 nm to about 100 nm, and often from about 25 nm to about 75 nm. However, it should be appreciated that the scope of disclosure is not limited to these particular thickness values of the valve metal layer (4). In general, the valve metal layer (4) can be of any thickness depending on various factors, such as, fabrication time, cost, availability, etc. In one particular embodiment, when W is used as the valve metal layer (4), the valve metal layer (4) thickness of about 500 nm is deposited. Yet in another embodiment, about 1 μm thick layer of valve metal layer (4) is deposited. In some embodiments where Ta is used as the valve metal layer (4), the thickness of valve metal layer (4) can vary from about 1 nm to about 1 μm or more. Still in other embodiments, the valve metal layer (4) is a metal alloy.

Typically, during the deposition of the valve metal layer (4) the composition comprising carrier body (1) and the metal layer (3), optionally with the adhesive layer, are held under vacuum for a period of time. The amount of vacuum and the time required for deposition of the valve metal layer (4) depends on many different factors, such as the valve metal layer (4) material to be deposited, the metal layer (3), thickness of the valve metal layer (4) desired, concentration of the valve metal layer (4) vapor within the deposition system (2), etc. In some embodiments, temperature of the composition comprising the carrier body (1) and the metal layer (3), optionally with an adhesive layer, is maintained at room temperature throughout the deposition. In other embodiments, the temperature is maintained in the range of from about 100° C. to about 200° C. However, it should be appreciated that the scope of the present disclosure is not limited to these temperatures. In fact, the temperature can be any temperature that is used by one skilled in the art of vapor deposition. In some embodiments, the carrier body (1), the metal layer (3), and the valve metal layer (4) are the material or layer.

Still in other embodiments, an adhesive layer (not shown) can be deposited in between the metal layer (3) and the valve metal layer (4). For example, a layer of titanium can be deposited on top of the metal layer (3) prior to depositing the valve metal layer (4). It is difficult to achieve tight binding between silicon wafer (carrier body (1)) and copper (metal layer (3)). Thus, to provide better attachment, an adhesive layer (e.g., titanium) can be placed on the surface of the carrier body (1) prior to depositing the metal layer (3). In this manner, one can achieve a good or tight bonding between the carrier body (1) and the metal layer (3).

As shown in FIG. 1, the method disclosed herein also includes depositing an anodization layer (5) on the surface of the composition comprising the carrier body (1), metal layer (3), and valve metal layer (4), optionally with adhesive layer(s). Exemplary materials suitable as anodization layer (5) include any non-ferrous metals known to one skilled in the art, such metals include but are not limited to, Al, Ti, and Mg. In one particular embodiment, the anodization layer (5) is Al or Ti. The thickness of the anodization layer (5) can be from about 10 nm to about 100 μm. In some embodiments, the thickness of the anodization layer (5) is from about 100 nm to about 100 μm, typically from about 250 nm to about 100 μm, often from about 500 nm to about 100 μm, and more often from about 1 μm to about 100 μm. However, it should be appreciated that the scope of the disclosure is not limited to any particular thickness of the anodization layer (5). In general, the thickness of the anodization layer (5) is determined by the depth of nanopores desired, infra. Thus, the thickness of the anodization layer (5) can be greater than 100 um or less than 10 nm. During the deposition of the anodization layer (5), the composition comprising the carrier body (1), metal layer (3), and valve metal layer (4), optionally with adhesive layer(s), is maintained at a temperature of from about 25° C. to about 1000° C., typically from about 25° C. to about 200° C., and often from about 50° C. to about 400° C. In other embodiments, the pressure is maintained at a range from about 1×10⁻⁷ mbar to about 1×10⁻³ mbar, typically from about 1×10⁻³ mbar to about 1×10⁻² mbar, and often from about 2×10⁻³ mbar to about 3×10⁻³ mbar during the deposition of anodization layer (5).

Typical deposition of the anodization layer (5) leads to a rough oxidized surface. An anodization of such a rough oxidized surface often leads to a highly disordered structure. To reduce or eliminate formation of such highly disordered structure during electrolysis (i.e., anodization), in some embodiments of the disclosure the surface of anodization layer (5) is polished. This surface polishing step can be done mechanically or it can be done electrochemically. In one particular embodiment, the polishing step comprises electrochemical polishing at a temperature of about 20° C. or less, typically at about 10° C. or less, often at about 5° C. or less. The electrochemical solution for polishing the surface of anodization layer (5) can include an acid (e.g., perchloric acid) in an organic solvent (e.g., ethanol). Other exemplary acids that can be used to polish the surface of anodization layer (5) include, but are not limited to, phosphoric acid, chromic acid, sulfuric acid, and a mixture there. Typical organic solvents for electrochemically polishing the surface of the anodization layer (5) include an alcohol (such as methanol, ethanol, propanol, isopropanol, sec-butanol, pentanol, etc.). The organic solvent can also be a mixture of an alcohol with one or more of aprotic organic solvents such as dimethylformamide (DMF), dimethyl sulfoxide (DMSO), ether, tetrahydrofuran, chloroform, carbon tetrachloride, dichloromethane, benzene, toluene, xylene, etc. Electrochemically polishing the surface of the anodization layer (5) typically involves placing the composite material having the anodization layer (5) in a solution comprising an acid in the organic solvent. The solution is then subjected to a current. In one embodiment, 15 V DC is used. In another embodiment, 25V, or 50V, or 1V is used. It should be appreciated that in some instances, the voltage can be held at one potential for some period of time and then be changed to another potential for another period of time.

The polishing of the surface of anodization layer (5) can also be achieved mechanically. For example, using a buffer or a sandpaper, etc. Such a mechanical polishing step is well known to one skilled in the art.

Referring again to FIG. 1, the composition comprising the anodization layer (5) is covered with a masking layer (6) for lithography. The masking layer (6) can be a metal or its oxide or nitride, a polymer or gel, or photoresist or any combination thereof. The masking layer (6) can be deposited by DC-sputtering or RF-sputtering; it could also be deposited by thermal or electron-beam evaporation or chemical vapor deposition or plasma-enhanced chemical vapor deposition. It could also be deposited by electrochemical deposition or spin coating or casting.

In one particular embodiment, the masking layer (6) can include SiO₂ which is then coated with a positive or negative photoresist. In this particular embodiment, the SiO₂ layer can be deposited by plasma enhanced chemical vapor deposition or chemical vapor deposition or evaporation. In still other embodiments of the method the SiO₂ is deposited by atomic layer deposition or another vapor phase deposition method. The photoresist is patterned through standard optical methods such as shadow masking or diffraction interferometry to produce a patterned mask layer (7). As can be seen, a lithographic development process creates exposed areas of the anodization layer (5) and covered or patterned mask layer (7). The exposed areas of the anodization layer (5) can be the size of the entire carrier body or they can be significantly smaller depending on the pattern. The pattern created by the lithographic process can be arrays of shapes, symbols, test structures, arrays of test structures, devices, arrays of devices, letters, writing, or a combination thereof. It can also be any two-dimensional image. In one embodiment, the process used to expose an area of layer 5 is done by spin coating a photoresist (i.e., masking layer (6)). The photoresist can be a positive photoresist or a negative photoresist. The photoresist can be exposed, or patterned, by UV-light, x-ray, or an electron beam, or another type of exposure known to one skilled in the art.

The composition comprising the carrier body (1), metal layer (3), valve metal layer (4), anodization layer (5), and patterned mask layer (7) with exposed areas of anodization layer (5), is introduced to or placed into an anodization system (8). The anodization system (8) can be attached to the deposition system (2) via vacuum or robotic transfer arm. The composition to be anodized can also be transferred manually from one system to another. The anodization system (8) can have a separate control for controlling the temperature of the composition or substrate to be anodized and the temperature of the electrolyte solution separately. The anodization system (8) can also include a control for adjusting the electrolysis voltage between material or the substrate to be anodized and a counter electrode.

In some embodiments, the anodization process comprises a two-step process as disclosed in a commonly assigned U.S. Provisional Patent Application No. 63/363,104, filed on Apr. 15, 2022, which hereby is incorporated herein by reference in its entirety. In another embodiment, the anodization process comprises a single step process. Still in another embodiment, the anodization process comprises a hard anodization process. Anodization process requires use of an anodizing electrolyte solution and voltage. The electrolyte solution used in anodization typically includes a solution of an acid. In general, any acid can be used in anodization electrolyte solution including, but not limited to, inorganic acids such as hydrochloric acid, perchloric acid, sulfuric acid, iodic acid, nitric acid, chromic acid, phosphoric acid, phosphorus acid, etc., organic acids such as oxalic acid, malic acid, sulfosalicylic acid, etc., as well as a combination of two or more acids. In some embodiments, the electrolyte solution for anodization comprises oxalic acid, sulfuric acid, hydrochloric acid, phosphoric acid, chromic acid, perchloric acid, ethanol, glycolic acid, tartaric acid, citric acid, malic acid, selenic acid, or a combination thereof. In addition, additives such as poly-ethylene glycol/ethylene glycol can be added to the electrolyte solution to control pore size or to extend the anodization voltage.

In one embodiment, the temperature of the electrolyte and the substrate comprising the anodization layer (5) is held at about 0° C. during the anodization process. Still in another embodiment, the temperature is held at about 10° C. or less.

The concentration of anodization electrolyte can vary depending on a variety of factors, such as the material to be anodized, amount of voltage applied, the nature of the solvent, type of electrolyte, etc. Thus, the concentration of the anodization electrolyte can be 1 M, greater than 1 M, or less than 1 M. In one particular embodiment where oxalic acid is used as an electrolyte, the concentration of oxalic acid is at least about 0.1 M.

The voltage used in the anodization process typically ranges from about 1 V to about 40 V. However, the scope of the disclosure is not limited to any particular voltage range. Thus, anodization voltage can range from about 150 V to about 190 V.

Referring again to FIG. 1, anodization in some embodiments produces an oxide plug (10) within the nanopores (9). Accordingly, in some embodiments, the method of disclosure includes removing the oxide plugs (10). Oxide plugs (10) are readily removed from the nanopores (9) by immersing or exposing the substrate to an oxide plug removal solution (i.e., removal solution). The removal solution is selected such that the solubility of the oxide plugs (10) is higher than the solubility of the inside surface (i.e., anodization layer (5)) of nanopores (9). As shown in FIG. 1, removal of oxide plugs (10) provides a solid substrate having a plurality of nanopores (9). Depending on the anodization conditions, domains of close-packed nanopore arrays are formed. In one particular embodiment, the average diameter of the nanopores ranges from about 20 nm to about 650 nm, and the length (i.e., depth) ranging from about 100 nm to about 50 um with interpore spacings or interpore distance (Dᵢₙₜ) ranging from about 50 nm to about 500 nm.

In some embodiments, the average diameter (Dₚ) of nanopores (9) ranges from about 500 nm to about 1 μm, typically from about 750 nm to about 500 nm, and often from about 100 nm to about 250 nm. One can increase the average diameter of nanopores after anodization and removal of oxide plugs (10) by immersing or exposing the substrate to, for example, 5% phosphoric acid at 38° C. for 70 minutes. In one specific example, contacting nanopores in anodized aluminum oxide (AAO) having an average pore diameter of 130±32 nm to 5% phosphoric acid resulted in increasing the average pore diameter to 400±31 nm. In some embodiments, the interpore distance (Dᵢₙₜ) of the substrate ranges from about 100 nm to about 100 μm, typically from about 150 nm to about 50 μm, often from about 200 nm to about 1 μm, and more often from about 250 nm to about 750 nm. In one particular embodiment, Dᵢₙₜ is 480±47 nm. The SSBs produced using the method disclosed herein.

The energy and power of the SSBs produced using the method of disclosure provided herein depend on many factors including, but not limited to, the average pore diameter, average interpore distance, pore length, i.e., the thickness of the anodization layer (5), type of cathode material, type of anode material, solid state electrolyte, etc. Accordingly, one can vary the anodization step (e.g., electrolyte used, concentration of electrolyte, anodization voltage, temperature of anodization process, etc.) to produce SSBs having a desired energy and power.

Once the plurality of nanopores (9) are produced in the solid substrate, it is subjected to a number of deposition processes in sequence to produce SSBs. Referring again to FIG. 1, the solid substrate comprising a plurality of nanopores (9) is placed in the deposition system (2). To produce a conformal solid-state battery from the solid substrate comprising a plurality of nanopores (9). As can be seen in the expanded view in FIG. 1, first a conformal electrical conductor (12) is deposited. In some embodiments, this conformal electrical conductor (12) is the cathode current collector if the next layer deposited is the cathode layer. If the next layer deposited is the anode layer then the conformal electrical conductor (12) is the anode current collector. In some embodiments, the electrical conductor (12) has an electrical resistivity of about 500×10³ (i.e., 5×10⁵) μΩ cm or less, typically about 250×10³ μΩ cm or less, often about 100×10³ μΩ cm or less, and most often about 75×10³ μΩ cm or less. In one specific embodiment, the conformal electrical conductor (12) has an electrical resistivity of about 53×10³ μΩ cm. In generally any solid electrical conductor can be used as long as it can be deposited using, for example, atomic layer deposition, chemical vapor deposition, electrochemical deposition, molecular layer deposition, plasma-enhanced chemical atomic layer deposition, plasma-enhanced chemical vapor deposition, or another type of vapor phase deposition method, or another type of physical deposition method, or any combination thereof, or any other method of depositing a layer of electrical conductor (12) conformally. In one particular embodiment, the electrical conductor (12) is TiN.

After the first electrical conductor (12) is conformally deposited, an electrode or the first electrode (13) (e.g., a cathode or an anode) is deposited at 13. In one particular embodiment, the first electrode (13) is a cathode. However, it should be appreciated that the first electrode (13) can be an anode rather than a cathode depending on the material used. In one specific embodiment, the first electrode (13) is a cathode having a capacity of about 50 mAh/g or more, typically about 75 mAh/g or more, often about 100 mAh/g or more, more often about 125 mAh/g or more, and most often about 175 mAh/g or more. In one embodiment, the first electrode is a cathodic electrode layer (13) having a capacity of 170 mAh/g or more. Yet in other embodiments, the cathode layer (13) has an operation voltage of about 2.5 V or more, typically about 3.0 V or more, and often from about 3.0 V to about 4.2V. Still in other embodiments, the cathode layer (13) has a capacity of about 170 mAh/g or more and operates in a voltage window wider than from about 3.0 V to about 4.2 V.

In general, any material that is suitable as a cathode and can be deposited using any of the processes disclosed herein can be used. In one particular embodiment, the cathode layer (13) comprises LiV₂O₅ or Li₂V₂O₅ or a metal phosphate such as a polymorph of lithium vanadium phosphate, lithium iron phosphate, or lithium titanium phosphate or another metal oxide such as a polymorph of LiCoO₂ (or a derivative NMC, NCA, etc.), LiMnO₂, LiNiO₂, LiMn₂O₄, LiCo2O4, LiFePO4, LiMnPO₄, LiCoPO₄, or a metal chalcogenides such as TiS₃, LiTiS₂, or a fluoride such as LiAlF₄, or a combination such as LiFeSO₄F or LiVPO₄F. Within this embodiment, in some instances the cathode layer (13) has a capacity of at least 147 mAh/g between 2.6-4.0 V or a capacity of 294 mAh/g between 2.0-4.0 V. It should be appreciated that the cathode layer (13) can be a Li-ion storing cathode, a Na-ion cathode, a Mg-ion storing cathode, or even an anion, e.g., F⁻, storing cathode.

Once the first electrode (13) is deposited, a conformal electrolyte (14) is deposited. The electrolyte keeps the cathode and anode substantially equally spaced (i.e., about 10% or less, typically about 5% or less, and often about 3% or less variation or difference in thickness) at the top of the pore and at the bottom of the pore. In some embodiments, solid electrolyte layer (14) comprises lithium phosphorus oxynitride (LiPON), lithium aluminum titanium phosphate (LATP), sodium super ionic conductor (NASICON, e.g., a sodium compound of the formula: Na₁₊ₓZr₂SiₓP₃₋ₓO₁₂, where 0<x<3), a lithium garnet (e.g., Li₆La₂BaTa₂O₁₂), lithium lanthanum titanate (LLTO), lithium super ionic conductor (LISICON) (e.g., Li₁₄ZnGe₄O₁₆), Thio-LISICON (e.g., Li_{3.4}Si_{0.4}P_{0.6}S₄), a composite (e.g., LiI—Al₂O₃), LiNbO₃, a hybrid organic/inorganic material, a polymer (such as polyethylene oxide (PEO), polyacrylonitrile (PAN), polymethyl methacrylate (PMMA)), polyvinylidene fluoride, a sulfide (e.g., LiSON, LiBSO), a fluoride (e.g., LiF), an oxy-sulfide (e.g., LiSO), as well as an oxy-fluoride (e.g., LiFO), or a combination or a composite thereof, e.g., PEO mixed with LiO₂. In one specific embodiment, the solid electrolyte layer (14) is a member of the LiPON (lithium phosphorus oxynitride) family of Li-ion conducting glasses. Still in other embodiments, the solid electrolyte layer (14) has an ionic conductivity of about 0.01×10⁻⁷ (i.e., 1×10⁻⁹ ) S/cm² or more, typically about 0.1×10⁻⁷ S/cm² or more, often 1×10⁻⁷ S/cm² or more, and still more often 10×10⁻⁷ (i.e., 1×10⁻⁶ ) S/cm² or more at 25° C.

In one specific embodiment, the electrolyte layer (14) is deposited by atomic layer deposition at a temperature of about 300° C. Yet in another embodiment, the electrolyte layer (14) is not a member of the LiPON family but still a ceramic material. Still in another embodiment, the electrolyte layer (14) is a polymer, or a sulfide, or a fluoride, or an oxy-sulfide, or an oxy-fluoride.

After the solid electrolyte layer (14) is deposited, a second electrode (15) is deposited. As stated previously, if the first electrode (13) is a cathode then the second electrode (15) is an anode, and vice versa. In one particular embodiment, the second electrode (15) is an anode. In this particular embodiment, the anode material has a capacity of at least about 100 mAh/g, typically at least about 500 mAh/g, often at least about 750 mAh/g, still more often at least about 1000 mAh/g, yet most often at least about 1250 mAh/g, and most often about 1500 mAh/g. In one specific embodiment, the anode electrode (15) is SnO₂. In this particular embodiment, the second electrode (15) capacity is about 1494 mAh/g.

In another particular embodiment, the anode electrode (15) is graphitic carbon. In this particular embodiment, the anode electrode (15) has a capacity of 372 mAh/g.

Referring again to the expanded view in FIG. 1, after the second electrode (15) is conformally deposited a second electrical conductor (16) is deposited. In some embodiments, the second electrical conductor (16) has an electrical resistivity of about 500×10³ (i.e., 5×10⁵) μΩ cm or less, typically about 250×10³ μΩ cm or less, often about 100×10³ μΩ cm or less, and most often about 75×10³ μΩ cm or less. In one specific embodiment, the conformal second electrical conductor (16) has an electrical resistivity of about 53×10³ μΩ cm. In generally any solid electrical conductor can be used as long as it can be deposited using, for example, atomic layer deposition, chemical vapor deposition, electrochemical deposition, molecular layer deposition, plasma-enhanced chemical atomic layer deposition, plasma-enhanced chemical vapor deposition, or another type of vapor phase deposition method, or another type of physical deposition method, or any combination thereof, or any other method of depositing a layer of second electrical conductor (16) conformally. In one particular embodiment, the second electrical conductor (16) is TiN.

In further embodiments of the disclosure, the method includes depositing a top metal contact (17). Exemplary top metal contact (17) materials that can be used include, but are not limited to, aluminum, gold, platinum, copper, titanium, chromium, ruthenium, tungsten, or an alloy thereof or a mixture thereof. The top metal contact (17) protects the nanostructures, i.e., conformally layered electrical cells underneath.

Still in some embodiments, as shown in FIG. 1 the top metal contact (17) is etched. This is represented by the three arrows on the second to the last figure in FIG. 1. Etching of the top metal contact (17) can be achieved using any of the methods known to one skilled in the art including, but not limited to, a wet chemical etching, a dry or plasma etching, ion milling, reactive ion etching, or a combination thereof. As can be seen in FIG. 1, the method of disclosure can also include etching of the second electrode (15) and the second electrical conductor (16). In this manner, a solid-state battery can be produced having a surface area that is larger than the footprint of the solid substrate.

Batteries produced using the method of this disclosure have higher energy and power relative to similar solid-state batteries with the same footprint, but without having conformally configured electric cells. Batteries produced by methods of the disclosure do not need external pressure to maintain high ionic conductivity at the electrode/electrolyte interface. In other embodiments, batteries produced by methods of the disclosure do not need catholytes, anolytes, or gels to maintain high ionic conductivity at the electrode/electrolyte interface. SSBs produced using the method of the disclosure can be used in any applications that require a power source. In particular, SSBs produced using the method of this disclosure are particularly used in medical implants (defibrillators, etc.), transportation, satellite, mining drilling equipment, etc. SSBs of the disclosure have both high power and high energy. Furthermore, because SSBs of the disclosure avoid any liquid electrolytes, they are particularly used in medical devices.

Additional objects, advantages, and novel features of this disclosure will become apparent to those skilled in the art upon examination of the following examples thereof, which are not intended to be limiting. In the Examples, procedures that are constructively reduced to practice are described in the present tense, and procedures that have been carried out in the laboratory are set forth in the past tense.

### EXAMPLES

### Example 1

AAO Template preparation: Al foil (99.99% pure) was purchased from Alfa Aesar. It was degreased in acetone for 10 minutes, dried, and placed in electropolishing solvent composed of 800 mL of 200 proof ethanol and 160 mL of 70% perchloric acid at a temperature of 3° C. The temperature of the solutions was set by a water bath chiller/heater unit. 15V was applied between the Al foil and stainless steel electrode for 5 minutes to electropolish the Al foil. The first anodization was performed in 0.3 M Oxalic acid at 8° C. under 40V for 6 hours. The disordered AAO that formed from the first anodization step was removed by placing it in the mixture of 70 mL of 85% phosphoric acid, 180 mL of 10% chromic acid, and 750 mL of water at 60° C. for 4 hours which left a patterned surface on the Al foil. This patterned aluminum was then used to grow ordered AAO films. By disrupting the anodization voltage from 40V to 20V and back to 40V with 2V step every 30 seconds, one interconnecting region can be added into the AAO film. By repeating this voltage disruption process, up to seven interconnecting regions are added in the AAO film. AAO film was left on the native Al foil for structural support. The pores were widened in 5% phosphoric acid at 38° C. at various times for different pore diameters.

Material deposition and Characterization: Atomic layer deposition was used to conformally coat the walls of high aspect ratio pores. Vanadyl triisopropoxide was pulsed for 2.5 seconds and O₃ was pulsed for 5 seconds alternatively in Beneq TFS 500 ALD system at 170° C. for the deposition of V₂O₅. For Ru metal, bis(ethylcyclopentadienyl) ruthenium was pulsed for 5 seconds and O₂ was pulsed for 6 seconds at 300° C. in home-built furnace reactor. Tescan FEG SEM and Hitachi Su-70 were used for morphological characterization. Due to the charging of the insulating nature of AAO, thin layer of carbon was sputtered on the bare AAO samples. After the deposition of V₂O₅, the electronic conductivity of V₂O₅ was high enough where the sample did not show any charging effect from the electron beam.

Electrochemical cells: LiClO₄ ACS reagent grade, anhydrous 99.7%>purity propylene carbonate was purchased from Sigma Aldrich. LiClO₄ was dried at 180° C. under vacuum for at least 24 hours before it was transferred to the glovebox where the electrolyte, 1 M LiClO₄ in PC, was prepared. T-cells were purchased from Swagelok and stainless steel rods were used for making contacts to the electrodes.

The half cells were prepared in these T-cells as three-electrode systems with two separate Li metals as the counter and reference electrodes. The air-tight seals allow these T-cells to be assembled in inert atmosphere of the glovebox and tested outside of the glovebox in air. The active mass was calculated from the change in mass of the AAO template before and after the deposition steps. A Biologic MPG-12 potentiostat was used for all electrochemical measurements.

### Results and Discussion

Template characterization: AAO templates with zero, four, and seven interconnecting layers were fabricated. AAO films with zero and seven interconnecting layers were prepared. The seven interconnecting layers are evenly distributed in 2.3 μm thick AAO films, while the straight pores contain no interconnections but are of the same thickness. Due to the insulating nature of the AAO, carbon was sputtered to minimize charging on the surface during SEM imaging. To create the electrodes within the AAO template, a ˜10 nm thick crystalline V₂O₅ film was deposited in the AAO templates using ALD. The successful deposition and its thickness was confirmed with SEM images of the AAO pore diameter before and after deposition. After the second anodization the pores diameters were widened. The pores after deposition were about 50 nm in diameter. This pore size was used for all tests in this study, except where the pores are denoted as being “61 nm” in diameter. After V₂O₅ deposition, the pores were about 61 nm. Detailed analysis of the pore diameters can be seen in Table below. Pore sizes of various AAO templates before and after 200 cycles of vanadium oxide deposition.

| | | | After 200 cycles |
|---|---|---|---|
| pore | | | of Vanadium |
| widening time | | Before ALD Pore | Oxide Pore |
| (minutes) | # Int. Layer | Diameter(nm) | Diameter (nm) |
| 11.5 | 0 | 75 +/− 2 | 48 +/− 3 |
| 11.5 | 7 | 70 +/− 3 | 51 +/− 4 |
| 15.5 | 0 | 83 +/− 2 | 61 +/− 3 |
| 15.5 | 7 | 80 +/− 4 | 63 +/− 4 |

After deposition, gold was sputtered on top of the AAO as a planar current collector. Using Swagelok T-cells with two Li foils as separate reference and counter electrodes, V₂O₅ electrodes with varying numbers of interconnecting layers were tested.

Electrochemical Testing of Interconnected V₂O₅ Electrodes: V₂O₅ was cycled within the one lithium insertion voltage window in electrodes with four and seven interconnections. It was observed that with more interconnecting layers, better capacity retention was seen at higher current densities. The current densities were defined by a “C” rate. A 1C rate is the gravimetric current density that needs to be applied to theoretically fully discharge the battery, in this case the cathode V₂O₅, in one hour. For one-lithium insertion voltage window, a 1C is 147 mA/g and for two-lithium insertion voltage window, a 1C is 294 mA/g.

After confirming the one-lithium insertion results, the impact of additional Li ion insertion into V₂O₅ electrodes was tested with interconnecting layers. The electrochemical window was increased (4V to 2V vs Li), enabling a second electron transfer reaction to occur. At low current densities, the interconnections had no significant impact on the capacity of the electrode. However, when the current density was increased, the electrode with more interconnecting layers had lower capacity, which is the opposite of what was observed in the one-lithium insertion regime. The capacity, or the total material usage, at high current densities is believed to be limited either by the Li ion transport or electron transport, depending on the electrode structure and the active material. There are mainly three types of transports: bulk ion transport which describes the movement of ions from the bulk of the electrolyte to the confined spaces in the porous structure, solid ion transport which describes the movement of ions from the surface of the active material into the bulk of the active material, and finally electron transport which describes the movement of electrons from the current collector through the active material. To deconvolute the ion and electron transport effects, experiments were designed to probe these properties independently.

Effect of Pore Size: To determine if the performance of V₂O₅ electrodes was limited by Li ion transport into the pores, the effect of the size of the pore opening on the results were considered. Using the SEM images of the AAO top-view before and after deposition, pore diameters were analyzed using ImageJ software's Analyze Particle function. Additionally, the cross-section images of the AAO templates and the template thickness were used to determine the dimensions of the pores for the estimation of Li ion concentration in the pores. To estimate the amount of Li ions available in each of the pores and the amount that need to diffuse from the bulk of the electrolyte into the confined pore spaces within the porous electrode for a two-Li insertion, a few assumptions were made for the calculations. The pores are assumed to be perfectly cylindrical and using the diameter of the AAO pore measured from the SEM images before and after ALD of V₂O₅, 70 nm and 50 nm, respectively, the V₂O₅ thickness was found to be 10 nm. The length of the AAO was 2.3 μm and using these values the nanotubular electrode volume was estimated. Utilizing the bulk density of V₂O₅, 3.36 g/cm³, the total V₂O₅ in the pore was estimated. The total number of Li ions in each of the pore was estimated by assuming that the internal volume of the tubular structure was still cylindrical. Utilizing the diameter of the pore opening after ALD, 50 nm, and a depth of 2.3 μm from the cross-section images, the total volume of electrolyte was estimated. Assuming the initial concentration within the pore was the same as the bulk, 1M LiClO₄ in PC electrolyte, the total number of Li ions per pore was estimated. The amount of Li ions and V₂O₅ in each pore was estimated to be 8.01×10⁻¹⁷ moles of V₂O₅/pore and 4.52×10⁻¹⁸ moles of Li ion/pore at rest. To lithiate the V₂O₅ to Li₂V₂O₅, each V₂O₅ unit requires two Li ions, indicating 1.60×10⁻¹⁶ moles of Li ions are needed per pore. With only 4.52×10⁻¹⁸ moles of estimated Li ion/pore, which accounts for only 3% of the total required Li ions for two full lithiations of V₂O₅ in each of the pores, 97% of the required Li ions still need to diffuse from the bulk of the electrolyte into the confined pores of the V₂O₅ nanotube electrodes. At low current densities, the rate of depletion of Li ions within the pores and the diffusion of Li ions from the bulk into the pores may be similar, allowing full material usage. As the current density increases, the rate of Li ion depletion increases as well. However, the rate in which the Li ions can diffuse from the bulk into the pores is limited by the diffusion coefficient and the diffusional cross-sectional area, i.e., the pore diameter, resulting in ion starvation where the ions are not diffusing fast enough to match the reaction rate. It has been shown that in highly confined electrode systems, it was the ion transport that was limiting the capacity at higher current densities. To explore the possibility of ion starvation in this system, the pore diameters were varied by changing the pore widening time of the AAO template. By altering the pore diameter, it is expected that a larger pore will be able to maintain larger ion transport capability than a smaller pore, due to the larger cross-sectional diffusional area.

With increased pore widening time, the final pore diameter was able to be increased from 50±3 nm to 61±4 nm. With the increased pore diameter, not only is the amount of Li ions available in the pore greater, but also the pore cross-sectional area is larger which increases the Li ion transport rate for Li ion diffusion from the bulk electrolyte into the pores. Current densities up to 10 C were chosen as it was enough to clearly show the difference in the impact of the pore diameters and interconnecting layers on the capacities. There was an increase in the capacity retention at various current densities with larger pore diameters, but the trend observed where more interconnections showed higher capacity loss is maintained even in the electrodes with larger pore openings. This observation suggests that even 50 nm pore diameter is enough to support the ion transport needed for high current densities.

### Example 2

3D solid state battery fabrication procedure: The 3D solid state battery fabrication was separated into two major categories, substrate fabrication and battery material deposition. For the 3D substrate fabrication, in one embodiment, a two-step anodization method was used to form highly ordered AAO on top of the Si wafer. The first AAO was a sacrificial layer where it was used to leave a patterned surface for the highly ordered second AAO layer. Multiple battery layers were deposited via ALD technique. The active area over the 3D substrate is then capped by sputtered Al. The excess battery materials around the 3D substrate are etched way. The 3D solid state battery is connected to the potentiostat via the Al cap for the anode connection and copper layer beneath the AAO for the cathode connection.

Metal Deposition on Si Wafer: Silicon wafers were purchased from University Wafers in three inch diameter, P type, with <100> orientation. The Si wafer was oxidized to form ˜500 nm of SiO₂ as an insulating layer. Metal layers were deposited with AJA ATC Orion 8 Sputtering system. All metals were sputtered at 300 W, unless it was specified, with various sputter times. Ti, Cu, and W were in the confocal position of the tool with the stage distance of 10 units while Al was in the center position of the tool with the stage distance of 70 units, unless it was specified. For all metal targets, the initial plasma was ignited at 20 sccm of Ar and 20 mTorr at 50 W of power with the shutter closed. The pressure was changed to 3 mTorr, and power was ramped to 300 W over one minute. At 300 W, the shutter was opened to start the deposition. Cu was unique in that plasma was ignited while the shutter was opened due to Ar flow issue into that particular confocal gun position. After the plasma was ignited, the shutter was closed and same changes in pressure and power were followed as other targets. Ti was sputtered for 120 seconds, Cu was sputtered for 2637 seconds, and W was sputtered for 3898 seconds. Al sputter time was varied to control the final AAO thickness. First Ar plasma was used to clean the wafer surface. Ti was sputtered first, followed by Cu, Ti, W, and Al.

Some samples were deposited without any substrate heating. These were annealed under Ar atmosphere at 400° C. for 4 hour and slowly cooled inside the annealing furnace to about 100° C. before they were removed. Other samples were sputtered with substrate heating at 400° C. and were not annealed.

Electropolish: The wafers with metal layers were electropolished to minimize surface roughness. 200 proof ethanol was purchased from PharmCo and perchloric acid was purchased from Fisher Scientific and Alfa Aesar. The electropolishing solution contained 180 mL of perchloric acid in 800 mL of ethanol. First ethanol was cooled in ice/water bath as the mixing was exothermic. Perchloric acid was added to the chilled ethanol under vigorous stirring. Once fully mixed, the solution was placed back in the ice bath until the solution temperature was between 1-2° C.

The wafer was placed in the anodization cell. The peltier stage was set to −2° C. in order to keep the electrolyte temperature as low as possible. The peltier stage could not chill the solution on its own and temperature of the electrolyte slowly rose. This was kept consistent between samples to ensure similar electropolishing rates. 15 V was applied with the wafer as the anode and stainless steel mesh as the cathode for 40 minutes. Lambda Genesys 600-8.5 was utilized as the power supply.

SiO₂ mask: The electropolished wafers were masked with SiO₂ in order to define the electroactive area. A negative photolithography technique was used. PECVD was used to deposit 500 nm of SiO₂ onto the electropolished wafer. HDMS was applied and was allowed to soak onto the wafer for 30 seconds. The excess HDMS was spun off at 4K rpm for 40 seconds. NR9-1500P photoresist was then applied and spun off at 4K rpm for 40 seconds. It was soft-baked at 150° C. for 1 minute. It was allowed to cool to room temperature before the wafer was placed under the shadow mask and exposed to 365 nm wavelength light for 20 seconds. The wafer was then placed in photoresist developer solution composed of RD6 and water in 3-to-1 ratio for 40 seconds. Undeveloped photoresist was removed by water and was blow dried under nitrogen. It was placed at 120° C. for 1 minute to hard bake the developed photoresist. The photo masked wafer was then allowed to cool to room temperature.

An Oxford Plasmalab System 100 was used to remove exposed SiO₂ on the wafer. Five rounds of 30 second etching were used for a total of 2.5 minutes to ensure that the photoresist was not burnt. The photomask then was removed in PG remover solution. The patterned SiO₂ wafer was then blow dried under nitrogen gas and stored until the anodization steps. The photoresist pattern can be seen in FIG. 4.3. There were mainly three different sized areas: 0.250 cm², 0.141 cm², and 0.071 cm².

Anodization: The first anodization was performed in 0.1M phosphoric acid in 1:4 v/v of ethanol to water solution, unless other specified, at −1.5° C. for 6 hours at 195 V. The first layer was removed with phosphoric acid: chromic acid etchant for 2 hours at 60° C. Second anodization conditions were the same as the first anodization. The second anodization was performed until the current dropped to the minimum current and was ran for extra one to two hours.

The pore widening step was separated into two steps. This was to maximize pore diameter of the AAO without weakening the AAO/Tungsten interface significantly which can lead to delaminating of the AAO from the W substrate. The AAO was first pore widened in 5% phosphoric acid in water at 38° C. for 40 minutes. WO₃ was selectively process was repeated for additional 30 minutes for a total of 70 minutes of pore widening.

ALD procedures: A Fiji 200 reactor was used for all of the battery material deposition. For TiN, tetrakis (dimethlyamido) titanium (TDMATi) and ammonia were used as the metal precursor and oxidant, respectively. For V₂O₅, vanadium tri-iospropoxide and ozone were used as the metal precursor and oxidant, respectively.

All depositions were performed under the exposure mode where the resident time of each gas vapor was significantly increased to maximize the conformality in high aspect ratio nanostructures such as the AAO scaffold unless specified.

Electrochemical Lithiation of V₂O₅: As deposited V₂O₅ was lithiated prior to the deposition of the LiPON and SnO₂. The electrolyte used was 1M LiClO₄ in PC. Between 2 and 5 mA was used to first lithiate the V₂O₅ cathode to 2.6 V vs Li and was held until the current reached a steady state. The electrode was then removed and washed several times with PC. It was then vacuum dried for least 8 hours before being placed back into the ALD reactor.

### Results and Discussion

Electropolishing: Electropolishing sputtered Al was significantly different than the conventional Al foil substrate normally used for the anodization. The conventional electropolishing is based on the process of forming aluminum hydroxide by the application of an oxidative potential on the aluminum. The aluminum oxide that is formed on the surface is then removed by the acidic electrolyte. The current density at the surface is dependent on the morphology of the surface. Highly rough surface will have higher current density, and therefore a higher oxidation rate of Al and removal leading to faster polishing rate, whereas a smoother surface will have lower current and lower Al removal rate. This difference in electropolishing rate leads to uniform, smooth surface finish on the Al. This process is conventionally performed under vigorous stirring of the electrolyte to aid in the removal of the aluminum oxide. However, for sputtered Al, electropolishing was seen. It also led to dull finishing near the edge of the electropolished area. The tungsten layer, darker than Al, was also seen on the top left area of the wafer. This uneven electropolished surface led to non-uniform AAO thickness throughout the wafer as some parts had thicker Al than other areas. Clear swirls can be also seen on the electropolished wafer, most likely due to the non-uniform flow of the electrolyte near the surface of the wafer. This would cause concentration gradient to form differently across the surface of the wafer. Areas of the wafer with high level of convection from stirring would have almost no concentration gradient and have fast electropolishing rate whereas areas with low level of convection would have thick diffusion layer and have low electropolishing rate.

In order to achieve more uniform electropolished, the stirring was removed. The electropolished area without stirring was highly uniform and highly reflective. With the lack of stirring in the electrolyte in the quiescent electropolishing, the buildup of the diffusion layer was proportional to the current density which was then dependent on the surface morphology. This meant that rougher the surface was, the faster it would build up the diffusion layer and quickly drop the reaction current but at a more flat surface, the diffusion layer would build up slower, leading to slower drop in the reaction current. This self-limiting electropolishing led to highly uniform Al surface for the next anodization step.

The current decayed exponentially as the surface roughness is decreased and the thickness of the diffusion layer increased. SEM and AFM measurements were used to not only qualitatively but also quantitatively compare the difference on the surface morphology of as deposited Al and electro polished Al. In the SEM, deposited Al showed large Al particles protruding randomly at the surface. After electropolishing, such protrusion was minimized and clear grain boundaries were observed. With AFM, the surface roughness was measured. The root-mean-squared roughness of the as-deposited Al was 120 nm whereas the electropolished Al was 29 nm.

Anodization: After the wafer was electropolished, the electrochemically active areas were defined by SiO₂ masking layer fabricated through lithography. Two-step anodization was performed to achieve highly ordered AAO structures. The initial anodization study required up to 16 hours of first anodization and low temperatures of 0° C. to achieve highly ordered AAO with 450 nm interpore distance.

Achieving such low temperature and keeping it consistent was difficult and led to local burning of the AAO due to the lack of efficient cooling of the Al despite having peltier stage directly underneath and separate electrolyte cooling. By adding ethanol, a successful first anodization current-time profile was achieved for the sputtered Al. The current was initially limited to 9.5 mA. The initial high current was from the oxidation of the Al surface with the formation of barrier-type layer. As the layer thickened, the current drops as the electric field drops until initial pores formed. As the porosity of the film increased, the current also increased until a steady-state current was achieved. This steady state current allowed the pore dimensions to equilibrate and the overall pores near the Al/AAO interface to become highly ordered. Due to the initial disordered porous regions, this layer was removed by acid, leaving highly ordered patterns on the Al surface. SEM images of the top of the AAO after the second anodization showed regions of hexagonally ordered AAO. In order to quantify the ordered nature of the AAO film, Fast Fourier Transform (FFT) was performed on the SEM images and the power density function spectrum was taken from the FFT image. The ordered nature of the AAO was quantified by the ratio of the peak intensity to the FWHM of the first peak in the power density spectrum.

The anodization of the sputtered Al resulted in wide range of average current densities from as low as 1.6 mA/cm² and as high as 3.7 mA/cm² with 1:4 EtOH to water ratio. When the ordered nature of the resulting AAO was plotted to the average current density, there was a trend where higher average current density resulted in more ordered AAO film. As expected, due to the lower current densities with the added EtOH, AAO films with EtOH resulted in loosely ordered structures whereas without ethanol achieved much higher ordered structures. However, the ordered structure required hard anodization for the first anodization layer, which again requires a relatively thick Al.

In order to minimize the negative effect of EtOH on the current density but still maintain the cooling capability, 1:9 EtOH to water ratio was used. This resulted in much higher range in the current densities, increasing from 3.5 mA/cm² to 4.4 mA/cm². All of the first anodizations were performed for 6 hours. With higher current density, a thicker first anodization layer would form. With a thicker first layer, there was more material in which the ordered pore arrangement could be further established.

The second anodization was performed until the W underneath the Al was anodized. In traditional AAO structure, the bottom of the pore is the barrier layer. The barrier layer is insulating and it must be removed in order to add a good electron pathway for the cathode in the SSB to the edge of the wafer. One method is to add another valve metal underneath the Al that has higher ionic conductivity than Al₂O₃ which can penetrate the barrier layer and then selectively removed. One such metal is W. Some have used W to fully anodize Al layer and then to form WO₃ nanoplugs that would penetrate the AAO barrier layer. The result of WO₃ formation after full utilization of the Al layer was the drop in the anodization current. WO₃ has higher ionic conductivity than Al₂O₃. This allowed formation of WO₃ through the barrier layer, creating a plug. As WO₃ have relatively higher acid stability than Al₂O₃, no dissolution occurs and continuously forms a thick oxide layer and causes a drop in the overall anodization current. Utilizing the difference in the chemical stability of Al₂O₃ and WO₃, WO₃ was selectively etched without damaging the Al₂O₃ of the AAO/W layer underneath the AAO pores. In order to maximize the 195 V samples, the 140 V samples were used first to optimize the WO₃ removal process. Before the WO₃ removal process, small plugs of WO₃ can be seen.

In order to fabricate a 3D solid state battery in AAO, a relatively thin AAO thickness was targeted. The samples that were anodized in both 1:4 and 1:9 ratios of EtOH and water showed that the AAO thickness is independent of the electrolyte composition. This allows the prediction of the final AAO thickness to tune the ALD recipes for different battery materials without the need to destroy the AAO sample for cross-sectioning characterization. This destructive characterization can be performed after the electrochemical testing to ensure the correct geometries were used for calculations.

Electrochemical characterization of Solid State Battery: In order to estimate the energy areal density of the 3D solid state films, several assumptions were made based on the experimental data. It was assumed that the energy density of the battery was limited by the cathode, V₂O₅, with a volumetric capacity of 38.6 μAh/cm2 at a nominal current density of 20 μA/cm². The anode, SnNx, with a volumetric capacity of 300 μAh/cm² at 20 μA/cm². Due to the larger volumetric density of the SnNx, the volumetric ratio of the cathode to the anode was maintained at 7.7. As AAO is highly a tunable 3D substrate, various geometric parameters area available and can be tailored as needed. With a 400 nm diameter, 450 nm interpore distance, and optimized thickness of each battery layers, a simple but also highly scalable 3D solid state battery can be achieved at 27.8 μWh per nominal cm² per um of the pore depth. With a 50 μm AAO substrate, the areal energy density is expected to have 1390 μWh/cm², significantly higher than the highest reported traditional thin film SSB. Based on the expected cell voltage, this specific 3D solid state battery is expected to have an energy density of 392 Wh/L where a currently available commercial thin film solid state battery EFL700A39 has 17 Wh/L. With the thin material thickness, it is also expected to achieve much higher power density as well.

One experiments for producing 3D SSB was to see how conformal the ALD materials can deposit in such high aspect ratio substrate. The ALD recipe was not optimized for high aspect ratio structures and was expected to have difficulty in depositing within the deeper pores. In one particular experiment, the cross-section using SEM images showed a gradient in the morphology of surface of the pores. Near the top, where the vapor phase precursors had most resident time, a good film growth can be seen from the increased surface roughness from the V₂O₅. However, in the lower portions of the pores where minimal precursor could access, there was a minimal film growth.

After about 18 μm down, only the smooth surface of the AAO can be seen as marked by the yellow line. While this was not a perfect sample, it was still used to gauge the effect of the AAO 3D substrate on the electrochemical behavior of the 3D cathode.

The capacity of the planar and 3D V₂O₅ were measured under various current densities. The areal capacity of the 3D scaffold V₂O₅ was only 19 times higher than the planar structure. Based on the geometry of the substrate, it should be 207 times higher. Without being bound by any theory, it is believed that this result was due to the difference in the 3D nominal area and planar nominal area on the 3D substrate. SEM images showed the cathode material was coated on all of the surface including both the 3D area and the planar area. This meant that the 2.00 cm² nominal area for the 3D substrate was too large. In the final version of the 3D SSB, the excess materials were etched and removed so only the active materials would be those on the AAO substrate. Since there was a separate planar data, the capacities of the planar portion of the 3D substrate was mathematically removed. This resulted in much higher difference between the capacities of the two substrates where at low current density, the 3D substrate had 113 times more capacity than the planar substrate. This increase in the capacity makes sense as only about half way down the pores were coated, 18 μm out of 35 μm thick AAO. This difference became even larger as the nominal current density was increased. At 500 μA/cm², the 3D substrate had 1330 times higher capacity. While the current density applied was the same between the 3D and planar substrate, due the larger surface area of the 3D substrate, the actual current density on the V₂O₅ was much lower and led to higher capacity retention.

### Conclusion

Anodized aluminum oxide was fabricated on a Si wafer as a high-aspect ratio template for a thin nanostructured 3D solid state battery. The ordered nature of the AAO was quantified by FFT and analysis of the power density spectrum. It was found that with higher current density, the higher ordered pores were formed. A highly linear function was found for the thickness of final AAO and the amount of charge passed during the second anodization to estimate the thickness of the AAO on wafer without the need to destroy the sample. Results showed that with high aspect ratio nanoscaffold such as the AAO, one can produce conformal SSBs using the ALD processes. 3D solid-state batteries of the disclosure showed promising results in terms of energy density and power density.

The foregoing discussion of the subject matter and embodiments have been presented for purposes of illustration and description. The foregoing is not intended to limit the disclosure to the form or forms disclosed herein. Although the description has included aspects of one or more embodiments and certain variations and modifications, other variations and modifications are within the scope of the disclosure, e.g., as may be within the skill and knowledge of those in the art, after understanding the present disclosure. It is intended to obtain rights which include alternative embodiments to the extent permitted, including alternate, interchangeable and/or equivalent structures, functions, ranges or steps to those claimed, whether or not such alternate, interchangeable and/or equivalent structures, functions, ranges or steps are disclosed herein, and without intending to publicly dedicate any patentable subject matter. All references cited herein are incorporated by reference in their entirety.

What is claimed is:

1. A method of producing a conformal solid-state battery from a solid substrate, wherein said solid substrate comprises:
a mask layer;
a patternable layer; and
a base layer, said method comprising:
patterning said mask layer using lithography to produce a patterned solid substrate comprising a patterned patternable layer surface;
nano-patterning said patterned patternable layer surface to produce a high-aspect ratio structured substrate comprising a plurality of nanopores within said patternable layer surface; and
conformally and sequentially depositing into said high-aspect ratio structured substrate a first current collector layer, an electrode layer, a solid electrolyte layer, a counter electrode layer, a counter current collector layer; and optionally a top contact layer to produce said conformal solid-state battery having a nanostructured solid substrate.

2. The method of producing a conformal solid-state battery of claim 1, wherein said base layer comprises Cu, Au, Pt, Ti, Ru, Ag, Pd, an oxide or a nitride thereof, an electrically conductive polymer, or a combination thereof.

3. The method of producing a conformal solid-state battery of claim 1, wherein said solid substrate further comprises a valve metal layer in between said patternable layer and said base layer.

4. The method of claim 3, wherein said valve metal layer comprises W, Ta, Ti, Nb, or a combination thereof.

5. The method of producing a conformal solid-state battery of claim 3, wherein said patternable layer comprises an anodizable metal.

6. The method of producing a conformal solid-state battery of claim 5, wherein said step of nano-patterning said patterned patternable layer surface comprises electrochemically anodizing said patternable layer until said valve metal layer begins to oxidize thereby forming a valve metal oxide plug.

7. The method of producing a conformal solid-state battery of claim 6, further comprising the step of removing said valve metal oxide plug.

8. The method of producing a conformal solid-state battery of claim 1, wherein said solid substrate further comprises a carrier body below said base layer.

9. The method of producing a conformal solid-state battery of claim 8, wherein said carrier body comprises a silicon wafer, a polymer, a web-tensioned polymer roll, a polymer foil, a metal foil, a metal disc, a polymer disc, a metal sheet, polymer sheet, a metal wire, a polymer wire, a metal fiber, a polymer fiber, a natural fiber, a weave of fibers, linen, or a combination thereof.

10. The method of producing a conformal solid-state battery of claim 1, wherein said masking layer comprises SiO₂ coated with a positive or a negative photoresist.

11. The method of producing a conformal solid-state battery of claim 1, wherein said step of patterning said mask layer comprises photolithography, interference lithography, electron beam lithography, optical lithography, x-ray lithography, ion beam lithography, diffraction lithography, direct write lithography, direct write laser lithography, laser lithography, or a combination thereof.

12. The method of producing a conformal solid-state battery of claim 1, wherein said step of conformally and sequentially depositing each of said first current collector layer, said electrode layer, said solid electrolyte layer, said counter electrode layer, said counter current collector layer; and optionally said top contact layer independently comprises an atomic layer deposition, chemical vapor deposition, electrochemical deposition, molecular layer deposition, plasma-enhanced chemical atomic layer deposition, plasma-enhanced chemical vapor deposition, or another type of vapor phase deposition method, or another type of physical deposition method, or any combination thereof.

13. The method of producing a conformal solid-state battery of claim 1, wherein said first current collector layer is a cathode current collector.

14. The method of producing a conformal solid-state battery of claim 13, wherein said electrode layer is a cathode layer.

15. The method of producing a conformal solid-state battery of claim 1, wherein said solid electrolyte layer has an ionic conductivity of at least 1×10⁻⁷ S/cm² at 25° C.

16. The method of producing a conformal solid-state battery of claim 15, wherein said solid electrolyte layer comprises lithium phosphorus oxynitride, lithium aluminum titanium phosphate (LATP), NASICON, a lithium garnet, lithium lanthanum titanate (LLTO), LISICON, Thio-LISICON, a composite of lithium electrolyte, a hybrid organic/inorganic material, a polymer, a lithium sulfide electrolyte, lithium fluoride (LiF), lithium oxy-sulfide (LiSO), lithium oxy-fluoride (LiFO), or a combination or composite thereof.

17. The method of claim 16, wherein said polymer comprises polyethylene oxide (PEO), polyacrylonitrile (PAN), polymethyl methacrylate (PMMA), polyvinylidene fluoride, or a combination thereof.

18. A conformal solid-state battery having an energy density of at least 1 μWh/cm² and a power density of at least 1 W/cm².

19. The conformal solid-state battery of claim 18, having a pore density of at least about 1.15×10⁶ pores/cm².

20. The conformal solid-state battery of claim 18, wherein said conformal solid-state battery has energy density of at least about 100 times more than a same solid-state battery in a planar state.

21. The conformal solid-state battery of claim 18, wherein an energy density of said conformal solid-state battery is at least 100 times greater than an energy density of a same SSB in a planar state at a current density of 10 μA/cm².

22. The conformal solid-state battery of claim 18, wherein an energy density of said conformal solid-state battery is at least 1,000 times greater than an energy density of a same SSB in a planar state at a current density of 0.5 mA/cm².

23. A conformal solid-state battery (SSB) comprising:
a valve metal layer (4) having a top surface and a bottom surface;
anodization layer (5) having a top surface and a bottom surface, wherein said bottom surface of said anodization layer (5) is in contact with said top surface of said valve metal layer (4), and wherein said anodization layer (5) comprises a plurality of pores each of which has an interior surface and a bottom surface, wherein said bottom surface extends towards said bottom surface of said anodization layer (5) and optionally extends partially into said valve metal layer (4);
a first electrical conductor (12) that is conformally layered on top surface of said anodization layer (5) and extending to and from said bottom surface;
a first electrode layer (13) that is conformally layered on top of said first electrical conductor (12);
a solid electrolyte layer (14) that is conformally layered on top of said first electrode layer (13);
a second electrode layer (15) that is conformally layered on top of said solid electrolyte layer (14); and
a second electrical conductor (16) that is conformally layered on top of said second electrode layer (15).

24. The conformal SSB according to claim 23, wherein a material of said valve metal layer (4) is selected from the group consisting of W, Ta, Ti, Nb, Nd, and a combination thereof.

25. The conformal SSB according to claim 23, wherein a material of said anodization layer (5) is selected from the group consisting of Al, Ti, Mg, and a combination thereof.

26. The conformal SSB according to claim 23, wherein said first electrical conductor (12) has an electrical resistivity of about 5×10⁵ μΩ cm or less.

27. The conformal SSB according to claim 23, wherein said first electrode layer (13) is a cathode comprising LiV₂O₅, Li₂V₂O₅, or a combination thereof.

28. The conformal SSB according to claim 23, wherein said solid electrolyte layer (14) has an ionic conductivity of at least about 1×10⁻⁹ S/cm² at 25° C.

29. The conformal SSB according to claim 23, wherein said solid electrolyte layer (14) comprises lithium phosphorus oxynitride, lithium aluminum titanium phosphate (LATP), sodium super ionic conductor (NASICON), a lithium garnet, lithium lanthanum titanate (LLTO), lithium super ionic conductor (LISICON), Thio-LISICON, a lithium composite, LiNbO₃, a hybrid organic/inorganic material, a polymer, a lithium sulfide, lithium fluoride, a lithium oxy-sulfide, lithium oxy-fluoride, or a combination or a composite thereof.

30. The conformal SSB according to claim 23, wherein said second electrode layer (15) has a capacity of at least about 500 mAh/g.

31. The conformal SSB according to claim 23, wherein said second electrical conductor (16) has an electrical resistivity of about 5×10⁵ μΩ cm or less.

32. The conformal SSB according to claim 23, wherein an average pore diameter is about 2 μm or less.

33. The conformal SSB according to claim 23, wherein an average pore depth of said anodization layer (5) is about 100 μm or less.

34. A method for producing a conformal solid-state battery (SSB) or an array of conformal solid-state batteries, said method comprising:
coating an anodization layer with a photoresist mask;
patterning said photoresist mask using a lithography process to produce a patterned anodization layer having a top surface and a bottom surface, wherein said top surface is coated with said patterned photoresist mask;
anodizing said patterned anodization layer to produce an anodized layer having a plurality of pores on said top surface of said anodization layer, wherein each of said pores has an interior surface and a bottom surface, wherein said bottom surface extends towards said bottom surface of said anodized layer;
coating said anodized layer with a first electrical conductor to produce a conformally coated first electrical conductor layer;
coating said first electrical conductor layer with a first electrode layer to produce a conformally coated first electrode layer;
coating said first electrode layer with a solid electrolyte layer to produce a conformally coated electrolyte layer;
coating said electrolyte layer with a second electrode layer to produce a conformally coated second electrode layer; and
coating said second electrode layer with a second electrical conductor layer to produce a conformally coated second electrode layer.

35. The method of claim 34, wherein at least one of said coating step is conducted using an atomic layer deposition process.

36. The method of claim 34, wherein said step of anodizing said patterned anodization layer comprises contacting said patterned anodization layer with an electrolytic solution under an electrolytic process.

37. The method of claim 36, wherein said electrolytic solution comprises oxalic acid, sulfuric acid, hydrochloric acid, phosphoric acid, chromic acid, perchloric acid, ethanol, glycolic acid, tartaric acid, citric acid, malic acid, selenic acid, or any combination thereof.
